(19) United States
(12) Patent Application Publication
(10) Pub. No.: US 2017/0345871 A1
(43) Pub. Date: Nov. 30, 2017

(54) ORGANIC INVERTER AND METHOD OF FORMING THE SAME

(71) Applicant: Agency for Science, Technology and Research, Singapore (SG)

(72) Inventors: Aung Ko Ko Kyaw, Singapore (SG); Jie Zhang, Singapore (SG); Changyun Jiang, Singapore (SG)

(21) Appl. No.: 15/607,877

(22) Filed: May 30, 2017

Related U.S. Application Data
(60) Provisional application No. 62/343,027, filed on May 30, 2016.

(51) Int. Cl. H01L 27/28; H01L 51/00; H01L 51/05

(52) U.S. Cl. CPC H01L 27/283; H01L 51/0096; H01L 51/0012; H01L 51/0558

(57) ABSTRACT

Various embodiments provide a method of forming an organic inverter including a first transistor and a second transistor. The method may include providing a substrate with a dielectric layer formed on top of the substrate; depositing a first semiconductor polymer layer on a first region of the dielectric layer; forming a first electrode and a second electrode on the first semiconductor polymer layer, thereby forming the first transistor located at the first region of the dielectric layer; forming a plurality of grooves on a surface of a second region of the dielectric layer; depositing a second semiconductor polymer layer on the second region of the dielectric layer; and forming a first electrode and a second electrode on the second semiconductor polymer layer, thereby forming the second transistor located at the second region of the dielectric layer.

### CROSS-REFERENCE TO RELATED APPLICATIONS

The present application claims the benefit of the U.S. provisional patent application No. 62/343,027 filed on May 30, 2016, the entire contents of which are incorporated herein by reference for all purposes.

### TECHNICAL FIELD

Embodiments relate generally to inverters, and in particular, relate to an organic inverter and a method of forming an organic inverter.

### BACKGROUND

Printed electronics is using graphic arts printing and functional polymer/composites to form electronics and optoelectronics. Due to their low cost and large area distributable nature, printed electronics have been quickly adopted by security packaging and anti-tapping applications. However, due to the printing resolution limitation, the printed circuits usually have low performance and the design is visible to the eye, which may be detrimental to security circuits.

An inverter circuit, a fundamental element of logic circuits, may include two transistors. In p-type or n-type inverter design, it is commonly using ratioed logic design to balance the switch speed and the noise margin of the two transistors. The ratio of the drive and load transistors is usually 3:1 to 4:1. This is achieved by physically making one transistor's channel width-to-length (W/L) ratio three or four times greater than another transistor.

FIG. 1 shows a schematic diagram of inverters according to the ratioed design. As shown in FIG. 1(a), the inverter 100 includes a first transistor 110 and a second transistor 120. The area of the second transistor 120 is increased to be larger than that of the first transistor 110. This results in larger area consumption, and higher impedance. FIG. 1(b) shows another inverter design, in which the inverter 150 includes a first transistor 160 and a second transistor 170. The channel length of the second transistor 170 is reduced to increase the W/L ratio of the second transistor 170. This is however restricted by printing resolution. In addition, both designs of the inverter circuit in FIGS. 1(a) and 1(b) are visible, which cannot be used for security circuits.

### SUMMARY

Various embodiments provide a method of forming an organic inverter including a first transistor and a second transistor. The method may include providing a substrate with a dielectric layer formed on top of the substrate; depositing a first semiconductor polymer layer on a first region of the dielectric layer; forming a first electrode and a second electrode on the first semiconductor polymer layer, thereby forming the first transistor located at the first region of the dielectric layer; forming a plurality of grooves on a surface of a second region of the dielectric layer; depositing a second semiconductor polymer layer on the second region of the dielectric layer; and forming a first electrode and a second electrode on the second semiconductor polymer layer, thereby forming the second transistor located at the second region of the dielectric layer.

Various embodiments provide an organic inverter. The organic inverter may include a substrate with a dielectric layer formed on top of the substrate. The organic inverter may include a first transistor located at a first region of the dielectric layer. The first transistor includes a first semiconductor polymer layer on the first region of the dielectric layer, and includes a first electrode and a second electrode on the first semiconductor polymer layer. The organic inverter may further include a second transistor located at a second region of the dielectric layer. The second transistor includes a second semiconductor polymer layer on the second region of the dielectric layer, and includes a first electrode and a second electrode on the second semiconductor polymer layer. The dielectric layer includes a plurality of grooves on a surface of the second region of the dielectric layer contacting the second semiconductor polymer layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments are described with reference to the following drawings, in which:

FIG. 1 shows a schematic diagram of inverters according to a ratioed design.

FIG. 2 shows a flowchart illustrating a method of forming an organic inverter according to various embodiments.

FIG. 3 shows a schematic diagram of an organic inverter according to various embodiments.

FIG. 4 shows a perspective view of a first transistor according to various embodiments.

FIG. 5 shows a perspective view of a second transistor according to various embodiments.

FIG. 6 shows a schematic diagram of an organic inverter design according to various embodiments.

FIG. 7 shows a schematic diagram of organic inverter circuits according to various embodiments.

FIG. 8 shows transfer characteristics of the first transistor of FIG. 4 according to various embodiments.

FIG. 9 shows transfer characteristics of the second transistor of FIG. 5 according to various embodiments.

FIG. 10 shows transfer characteristics of the organic inverter of FIG. 3 according to various embodiments.

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized, and structural and logical changes may be made without departing from the scope of the invention. The various embodiments are not necessarily mutually exclusive, as some embodiments can be combined with one or more other embodiments to form new embodiments.

In the specification the term “comprising” shall be understood to have a broad meaning similar to the term “including” and will be understood to imply the inclusion of a stated integer or step or group of integers or steps but not the exclusion of any other integer or step or group of integers or steps. This definition also applies to variations on the term “comprising” such as “comprise” and “comprises”.

It should be understood that the terms “on”, “under”, “top”, “bottom”, etc., when used in the following description are used for convenience and to aid understanding of relative positions or directions, and not intended to limit the orientation of any device or structures or any part of any device or structure.

Various embodiments provide an organic inverter and a method of forming an organic inverter, wherein the organic inverter can be used for security circuit in a compact design with improved integration density, without restriction on printing resolution.

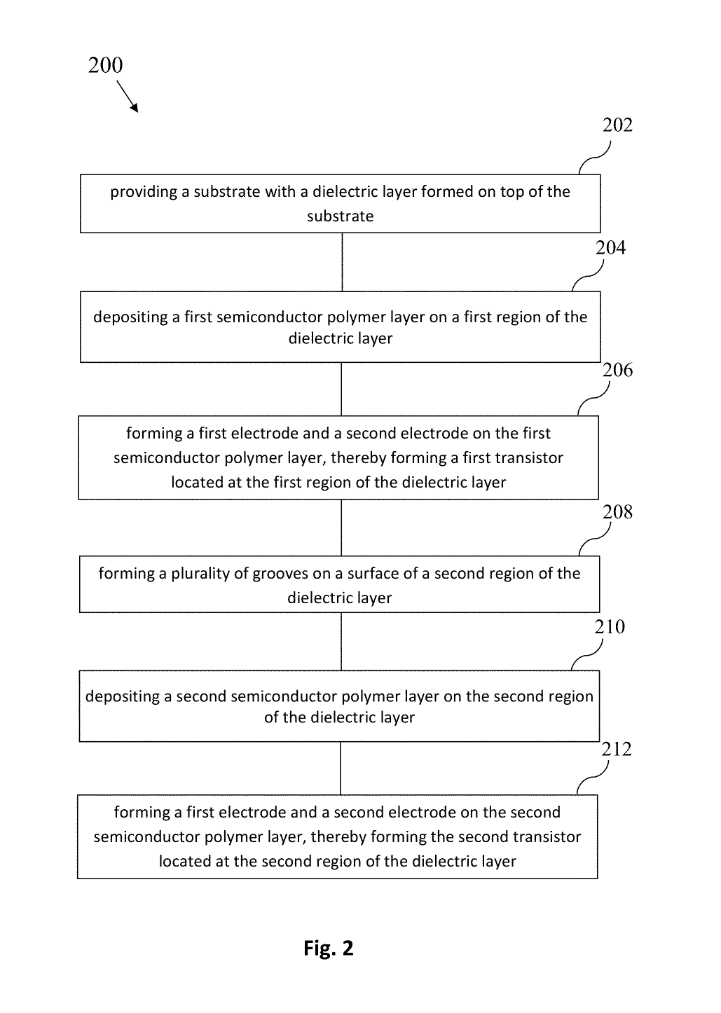

FIG. 2 shows a flowchart 200 illustrating a method of forming an organic inverter according to various embodiments.

At 202, a substrate with a dielectric layer formed on top of the substrate is provided.

At 204, a first semiconductor polymer layer is deposited on a first region of the dielectric layer.

At 206, a first electrode and a second electrode are formed on the first semiconductor polymer layer, thereby forming a first transistor located at the first region of the dielectric layer.

At 208, a plurality of grooves are formed on a surface of a second region of the dielectric layer.

At 210, a second semiconductor polymer layer is deposited on the second region of the dielectric layer.

At 212, a first electrode and a second electrode are formed on the second semiconductor polymer layer, thereby forming a second transistor located at the second region of the dielectric layer.

Accordingly, the organic inverter including the first transistor and the second transistor is formed.

In other words, the method according to various embodiments may include providing a substrate with a dielectric layer formed on a top surface of the substrate. The dielectric layer includes a first region and a second region, wherein a plurality of grooves are formed on a top surface of the second region of the dielectric layer. A first semiconductor polymer layer is deposited on the first region of the dielectric layer, and a second semiconductor polymer layer is deposited on the second region of the dielectric layer where the plurality of grooves are formed. A first electrode and a second electrode of a first transistor are formed on the first semiconductor polymer layer, and a first electrode and a second electrode of the second transistor are formed on the second semiconductor polymer layer.

It is understood that the processes or steps 202-212 above may not be carried out in sequence, and may be carried out in any suitable order according to various embodiments. In an exemplary embodiment, the method may be carried out in the order of 202, 204, 206, 208, 210 and 212. In another exemplary embodiment, the method may be carried out in the order of 202, 208, 210, 212, 204, and 206. In a further exemplary embodiment, the method may be carried out in the order of 202, 204, 208, 210, 206, and 212.

According to various embodiments, the substrate may be a silicon substrate. The substrate may be an undoped substrate, which may include selectively heavily doped regions under the first region and the second region of the dielectric layer. In an exemplary embodiments, the substrate may include a first heavily doped region under the first region of the dielectric layer, a second heavily doped region under the second region of the dielectric layer, wherein the first heavily doped region is electrically isolated from the second heavily doped region. The first heavily doped region and the second heavily doped region may form a respective third electrode of the first transistor and the second transistor, e.g. a control electrode, e.g. a gate electrode or a base electrode.

According to various embodiments, the substrate may be or may include a rigid substrate such as a glass substrate, or a flexible substrate such as a polyethylene terephthalate (PET) substrate, a polyethylene naphthalate (PEN) substrate or a polyimide substrate. The respective third electrode of the first transistor and the second transistor may be formed in the substrate under the first region and the second region of the dielectric layer.

According to various embodiments, the dielectric layer may include one of SiO₂, polystyrene, polymethyl methacrylate (PMMA), polyvinyl pyrrolidone (PVP), polyvinyl alcohol (PVA) or polydimethylsiloxane (PDMS). The thickness of the dielectric layer may be about 200 nm.

According to various embodiments, the method may include forming the first transistor and the second transistor with substantially the same channel width-to-length (W/L) ratio. In various embodiments, the first transistor and the second transistor may have the same W/L ratio with 50% tolerance.

In various embodiments, the first semiconductor polymer layer may be deposited on the first region of the dielectric layer by one of spin coating, drop casting, dip coating, inkjet, grovure printing, flexographic printing, Langmuir-Blodgett depositions, or doctor blading.

In various embodiments, the plurality of grooves may be formed by scratching the surface of the second region of the dielectric layer using diamond lapping film. The grooves may be formed by manually scratching the surface of the second region of the dielectric layer in a predetermined direction using diamond lapping film. In other embodiments, the grooves may be formed by scratching the surface of the dielectric layer using a tool which is configured to control the applied pressure and the scratching direction precisely.

In various embodiments, the plurality of grooves may include nanoscale grooves, with the dimensions (e.g., at least one of the depth or the width/diameter) of the grooves in the nanoscale. The nanoscale grooves may be referred to as nanogrooves. According to various embodiments, one or both of the depth and the width/diameter of the grooves may be in the range of about 1 nm to 5 nm, for example, 1 nm to 2 nm.

In various embodiments, the plurality of grooves is at least substantially parallel to each other. In other words, longitudinal axes of the plurality of grooves may extend along substantially the same direction.

According to various embodiments, the second semiconductor polymer layer may be directionally deposited on the second region of the dielectric layer by one of slot-die coating, dip coating, grovure printing, flexographic printing, Langmuir-Blodgett depositions, or doctor blading. In various embodiments, the second semiconductor polymer layer may be directionally deposited along a direction at least substantially parallel to longitudinal axes of the plurality of grooves.

According to various embodiments, the second semiconductor polymer layer may be deposited on the second region of the dielectric layer by one of drop casting or inkjet printing.

According to various embodiments, the first electrode and the second electrode of the second transistor may be formed such that a channel length between the first electrode and the second electrode is at least substantially parallel to longitudinal axes of the plurality of grooves.

According to various embodiments, at least one of the first semiconductor polymer layer or the second semiconductor polymer layer may include one of PCDTPT (poly[4-(4,4-dihexadecyl-4H-cyclopenta[1,2-b:5,4-b]dithiophen-2-yl)-alt-[1,2,5]thiadiazolo-(3,4c)pyridine]), P3HT (poly(3-hexylthiophene)), PPV (poly(p-phenylene vinylene)), or PBTTT (poly(2,5-bis(3-alkylthiophen-2-yl)thieno(3,2-b)thiophene)).

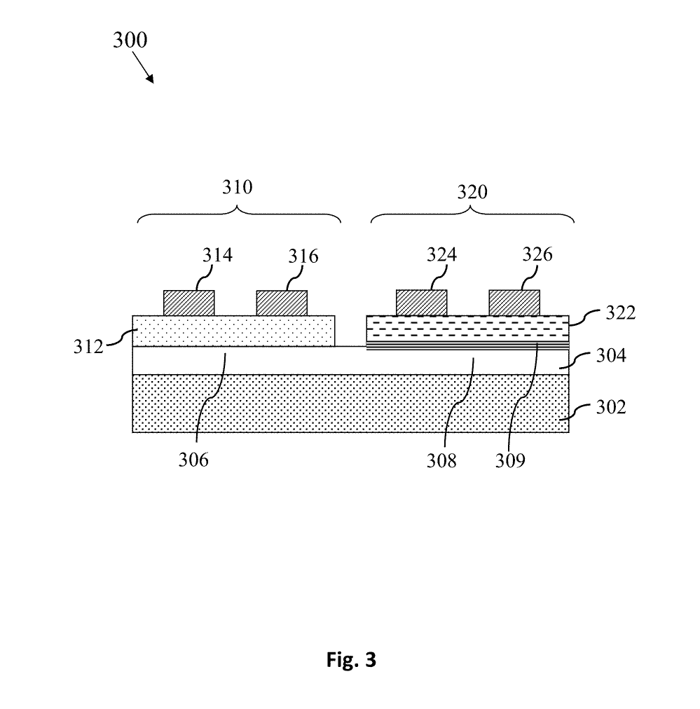

FIG. 3 shows a schematic diagram of an organic inverter 300 according to various embodiments. Various embodiments described in the method 200 of FIG. 2 above may be used to form the organic inverter 300 of FIG. 3, and are analogously valid for the embodiments of the organic inverter 300 described herein, and vice versa.

As shown in FIG. 3, the organic inverter 300 includes a substrate 302 with a dielectric layer 304 formed on top of the substrate 302. The organic inverter 300 includes a first transistor 310 located at a first region 306 of the dielectric layer 304. The first transistor 310 includes a first semiconductor polymer layer 312 on the first region 306 of the dielectric layer 304, and includes a first electrode 314 and a second electrode 316 on the first semiconductor polymer layer 312. The organic inverter 300 further includes a second transistor 320 located at a second region 308 of the dielectric layer 304. The second transistor 320 includes a second semiconductor polymer layer 322 on the second region 308 of the dielectric layer 304, and includes a first electrode 324 and a second electrode 326 on the second semiconductor polymer layer 322. The dielectric layer 304 includes a plurality of grooves 309 on a surface of the second region 308 of the dielectric layer 304 contacting the second semiconductor polymer layer 322.

According to various embodiments, the dielectric layer 304 may be formed on a top surface of the substrate 302. The plurality of grooves 309 may be located on a top surface of the second region 308 of the dielectric layer 304. The top surface of the second region 308 is contacting the second semiconductor polymer layer, and is opposite to a bottom surface of the dielectric layer 304 contacting the substrate 302. The second semiconductor polymer layer 322 is located on the top surface of the second region 308 where the grooves 309 are located.

According to various embodiments, the substrate 302 may be a silicon substrate. The substrate 302 may be an undoped substrate, which may include selectively heavily doped regions (not shown) under the first region 306 and the second region 308 of the dielectric layer 304. In an exemplary embodiments, the substrate 302 may include a first heavily doped region under the first region 306 of the dielectric layer 304, a second heavily doped region under the second region 308 of the dielectric layer 304, wherein the first heavily doped region is electrically isolated from the second heavily doped region. The first heavily doped region and the second heavily doped region may form a respective third electrode of the first transistor 310 and the second transistor 320, e.g. a control electrode, e.g. a gate electrode or a base electrode.

According to various embodiments, the substrate 302 may be or may include a rigid substrate such as a glass substrate, or a flexible substrate such as a polyethylene terephthalate (PET) substrate, a polyethylene naphthalate (PEN) substrate, or a polyimide substrate. The respective third electrode of the first transistor 310 and the second transistor 320 may be formed in the substrate under the first region and the second region of the dielectric layer.

According to various embodiments, the dielectric layer 304 may be a layer including one of SiO₂, polystyrene, polymethyl methacrylate (PMMA), polyvinyl pyrrolidone (PVP), polyvinyl alcohol (PVA) or polydimethylsiloxane (PDMS). The thickness of the dielectric layer may be about 200 nm.

According to various embodiments, the first transistor 310 may further include a third electrode (not shown in FIG. 3) in the substrate 302. The third electrode of the first transistor 310 may be a control electrode, e.g. a gate electrode or a base electrode, and may be located under the first region 306 of the dielectric layer 304. According to various embodiments, the second transistor 320 may further include a third electrode (not shown in FIG. 3) in the substrate 302. The third electrode of the second transistor 320 may be a control electrode, e.g. a gate electrode or a base electrode, and may be located under the second region 308 of the dielectric layer 304. The third electrode of the first transistor 310 and the third electrode of the second transistor 320 are electrically isolated from each other, e.g., by an insulating layer arranged between the third electrode of the first transistor 310 and the third electrode of the second transistor 320. In an illustrative embodiment, the third electrode of the first transistor 310 and/or the third electrode of the second transistor 320 may be each formed as a heavily doped region in the substrate 302 under the respective first region 306 and the second region 308 of the dielectric layer 304.

According to various embodiments, the first electrode 314 of the first transistor 310 may be one of a drain electrode and a source electrode (or one of an emitter electrode and a collector electrode), and the second electrode 316 of the first transistor 310 may be the other one of the drain electrode and the source electrode (or the other one of an emitter electrode and a collector electrode). In various embodiments, the first electrode 324 of the second transistor 320 may be one of a drain electrode and a source electrode (or one of an emitter electrode and a collector electrode), and the second electrode 326 of the second transistor 320 may be the other one of the drain electrode and the source electrode (or the other one of an emitter electrode and a collector electrode).

According to various embodiments, the first transistor 310 and the second transistor 320 may have substantially the same channel width-to-length (W/L) ratio. In various embodiments, the first transistor 310 and the second transistor 320 may have the same W/L ratio with 50% tolerance.

According to various embodiments, at least one of the first semiconductor polymer layer 312 or the second semiconductor polymer layer 322 may include one of PCDTPT (poly[4-(4,4-dihexadecyl-4H-cyclopenta[1,2-b:5,4-b]dithiophen-2-yl)-alt-[1,2,5]thiadiazolo-(3,4c)pyridine]), P3HT (poly(3-hexylthiophene)), PPV (poly(p-phenylene vinylene)), or PBTTT (poly(2,5-bis(3-alkylthiophen-2-yl)thieno(3,2-b)thiophene)).

According to various embodiments, polymer chains of the first semiconductor polymer layer 312 are randomly aligned.

In various embodiments, the first semiconductor polymer layer 312 may be deposited on the first region 306 of the dielectric layer 304 by one of spin coating, drop casting, dip coating, inkjet, grovure printing, flexographic printing, Langmuir-Blodgett depositions, or doctor blading.

According to various embodiments, polymer chains of the second semiconductor polymer layer 322 are aligned substantially along a direction from the first electrode 324 to the second electrode 326 of the second transistor 320. In other words, the polymer chains of the second semiconductor polymer layer 322 are aligned substantially along a direction of the channel between the first electrode 324 and the second electrode 326 of the second transistor 320. The polymer chains of the second semiconductor polymer layer 322 are aligned, due to the plurality of grooves 309 located on the top surface of the dielectric layer 304.

In various embodiments, the plurality of grooves 309 may include a plurality of nanoscale grooves with a depth in a range of about 1 nm to 5 nm, for example, 1 nm to 2 nm. The nanoscale grooves 309, also referred to nanogrooves, may refer to the grooves with their dimensions, e.g., at least one of the depth or the width/diameter, in the nanoscale. In various embodiments, the width or the diameter of the plurality of grooves 309 may be in the range of about 1 nm to 5 nm, for example, 1 nm to 2 nm. The length of the nanoscale grooves 308 may extend substantially along a length of the second semiconductor polymer layer 322. In various embodiments, the plurality of grooves 309 may be located substantially on the entire surface of second region 308 on which the second semiconductor polymer layer 322 is formed.

In various embodiments, the plurality of grooves 309 is at least substantially parallel to each other. In other words, longitudinal axes of the plurality of grooves 309 may extend along substantially the same direction. According to various embodiments, a channel length between the first electrode 324 and the second electrode 326 of the second transistor 320 is at least substantially parallel to the longitudinal axes of the plurality of grooves 309.

In various embodiments, the plurality of grooves 309 may be formed by scratching the surface of the second region 308 of the dielectric layer 304 using diamond lapping film. The grooves 309 may be formed by manually scratching the surface of the second region 308 of the dielectric layer 304 in a predetermined direction using diamond lapping film. In other embodiments, the grooves 309 may be formed by scratching the surface of the dielectric layer 304 using a tool which is configured to control the applied pressure and the scratching direction precisely.

According to various embodiments, the second semiconductor polymer layer 322 may be directionally deposited on the second region 308 of the dielectric layer 304 by one of slot-die coating, dip coating, grovure printing, flexographic printing, Langmuir-Blodgett depositions, or doctor blading. In various embodiments, the second semiconductor polymer layer 322 may be directionally deposited along a direction at least substantially parallel to longitudinal axes of the plurality of grooves 309. Due to the plurality of grooves 308, the polymer chains of the second semiconductor polymer layer 322 are aligned.

According to various embodiments, the second semiconductor polymer layer 322 may also be deposited on the second region 308 of the dielectric layer 304 by one of drop casting or inkjet printing.

The embodiments of FIG. 3 show that the first semiconductor polymer layer 312 and the semiconductor polymer layer 322 are spaced apart with spacing between each other. It is understood that the space between the first semiconductor polymer layer 312 and the semiconductor polymer layer 322 may be filled with other materials, such as dielectric materials, in various embodiments. In other embodiments, the first semiconductor polymer layer 312 and the semiconductor polymer layer 322 may be adjacent to and contact each other without space in between.

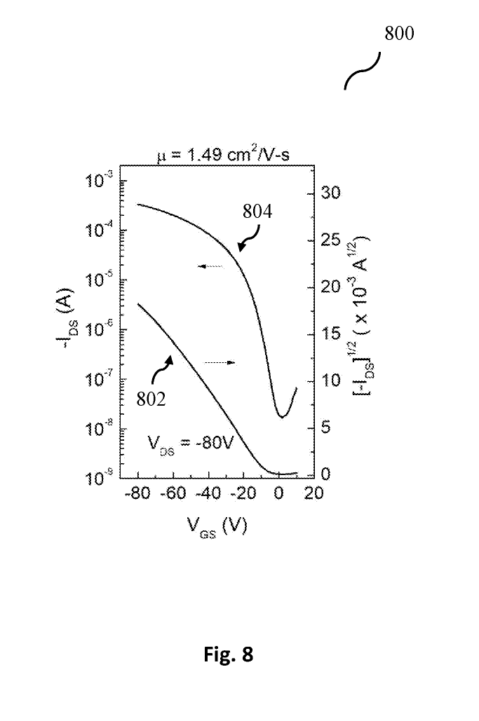

According to various embodiments, the second transistor 320 with the aligned second semiconductor polymer layer has a higher performance than the first transistor 310, as illustrated in FIGS. 8-10 below, even when the W/L ratios of the first transistor 310 and the second transistor 320 are substantially the same. Accordingly, various embodiments provide a ratioed logic design of the inverter 300 based on tuning or manipulating the performance of the transistors, but not based on geometrical changes of the transistors.

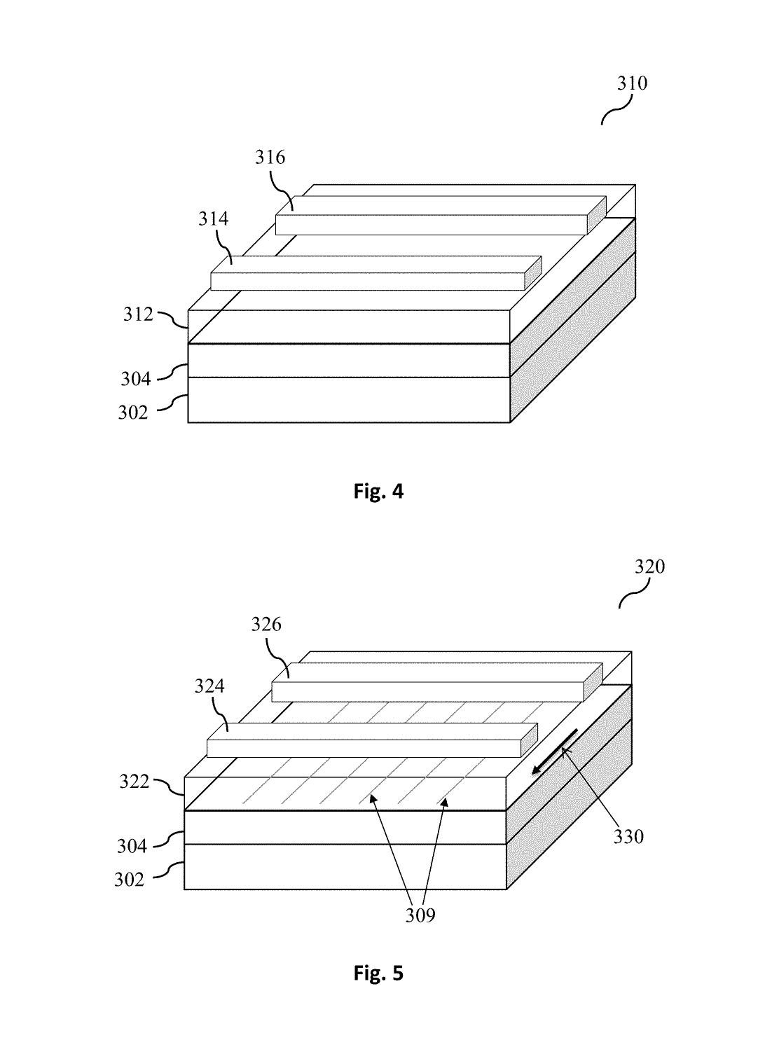

FIG. 4 shows a perspective view of the first transistor 310 according to various embodiments.

As shown in FIG. 4, the first transistor 310 is formed on the substrate 302. The first transistor includes the substrate 302, the dielectric layer 304 on top of the substrate 302, the first semiconductor polymer layer 312 on the dielectric layer 304, the first electrode 314 and the second electrode 316 on the first semiconductor polymer layer 312.

FIG. 5 shows a perspective view of the second transistor 320 according to various embodiments.

The second transistor 310 is formed on the substrate 302. The second transistor includes the substrate 302, the dielectric layer 304 on top of the substrate 302, the second semiconductor polymer layer 322 on the dielectric layer 304, the first electrode 324 and the second electrode 326 on the second semiconductor polymer layer 322. In the second transistor 310, the plurality of grooves 309 are provided on the surface of the dielectric layer 304, on which the second semiconductor polymer layer 322 is formed.

In various embodiments, the plurality of grooves 309 is at least substantially parallel to each other. As shown in the embodiments of FIG. 5, longitudinal axes of the plurality of grooves 309 may extend along substantially the same direction 330. According to various embodiments, a channel length between the first electrode 324 and the second electrode 326 of the second transistor 320 is at least substantially parallel to the longitudinal axes of the plurality of grooves 309, i.e. parallel to the direction 330.

In various embodiments, the second semiconductor polymer layer 322 may be directionally deposited substantially along the direction 330. In an exemplary embodiment when slot-die coating is used to deposit the second semiconductor polymer layer 322, the direction 330 may represent the direction of movement of slot-die during casting of polymer.

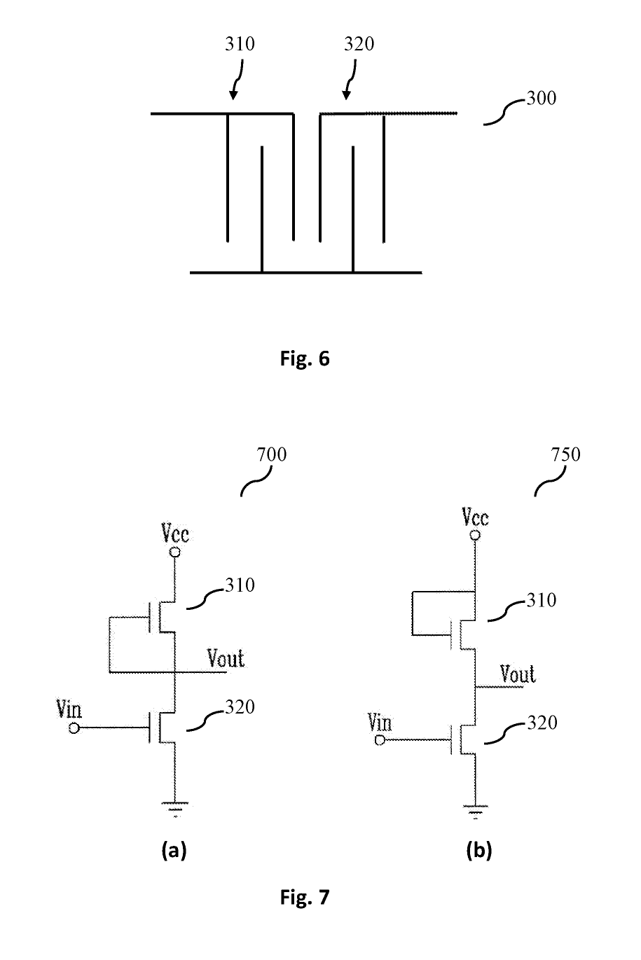

FIG. 6 shows a schematic diagram of an organic inverter design according to various embodiments.

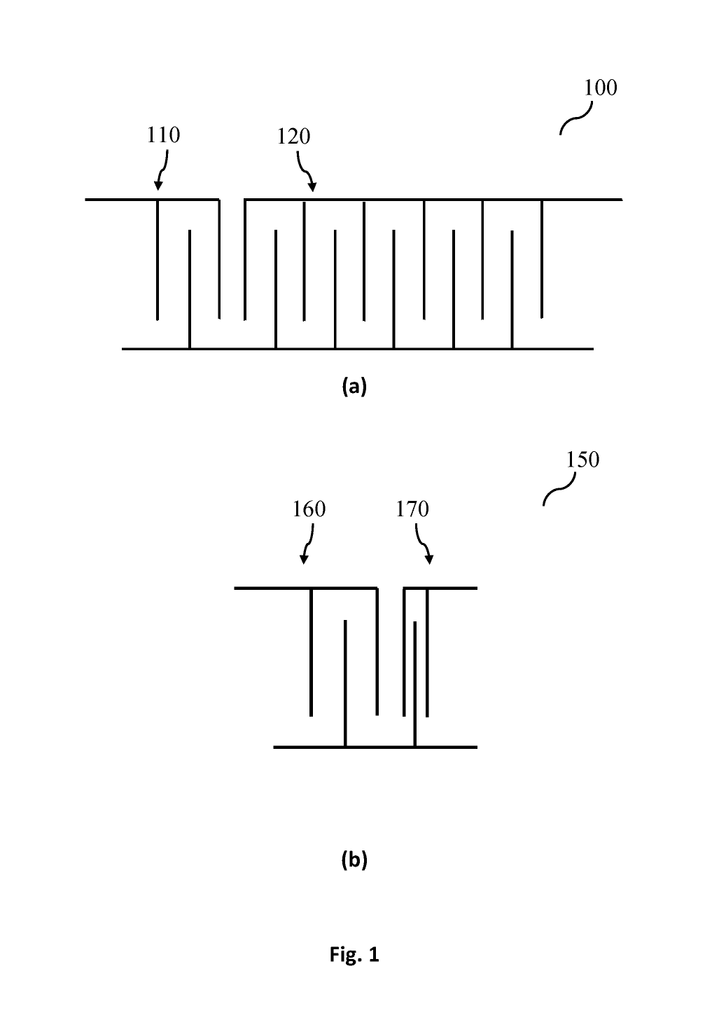

The organic inverter design of FIG. 6 may be the organic inverter 300 described above, including the first transistor 310 and the second transistor 320. According to various embodiments, the first transistor 310 and the second transistor 320 may have substantially the same channel width-to-length (W/L) ratio. Accordingly, from the inverter design of FIG. 6, the two transistors 310, 320 may have the same geometric appearance, and thus the function of the circuit 300 cannot be determined from the appearance as compared to the circuit design of FIGS. 1(a) and 1(b).

The first transistor 310 and the second transistor 320 may be electrically connected to form the organic inverter 300. In various embodiments, one of the first electrode 314 and the second electrode 316 of the first transistor 310 may be electrically connected to one of the first electrode 324 and the second electrode 326 of the second transistor 320.

FIG. 7 shows a schematic diagram of organic inverter circuits according to various embodiments.

FIG. 7(a) shows an organic inverter circuit 700 including the first transistor 310 and the second transistor 320 connected together, with one electrode of the first transistor 310 connected with one electrode of the second transistor 320. Similarly, FIG. 7(b) shows an organic inverter circuit 750 including the first transistor 310 and the second transistor 320 connected together, with one electrode of the first transistor 310 connected with one electrode of the second transistor 320. The difference between the inverter circuits 700, 750 is that the control electrode of the first transistor 310 may connect to the output voltage Vout in the circuit 700, or may connect to the supply voltage Vcc in the circuit 750. In various embodiments, the first transistor 310 and the second transistor 320 may be connected in any suitable manner to form the organic inverter 300.

In the following, an exemplary embodiment of a method or process of forming the first transistor 310 and the second transistor 320 described in various embodiments above is described. Various embodiments described in the method 200 and the inverter 300 above are analogously valid for the following process, and vice versa.

The two transistors 310 and 320 may be separately fabricated on the substrate 302 and the dielectric layer 304, for example, an undoped Si wafer 302 with a 200 nm-thick thermal oxide grown SiO₂ layer 304. The Si wafer 302 may be selectively doped, for example, under the region 306 and under the region 308 of the dielectric layer 304, to form a first heavily doped region and a second heavily doped region laterally arranged and electrically isolated from each other. The two transistors 310 and 320 may be formed using bottom-gate and top-contact configuration.

In order to make the two transistors 310, 320 have different performance, for example, 3-4 times difference, uniaxial nanogrooves 309 with a depth of 1-2 nm are selectively fabricated on the SiO₂ surface where the higher-performance transistor (e.g. the second transistor 320) is located to induce alignment of polymer chains. The nanogrooves 309 may be fabricated by scratching the SiO₂ surface with diamond lapping film. The SiO₂ surface where the lower-performance transistor (e.g. the first transistor 310) is located is made intact, i.e. without nanogrooves.

Semiconductor polymer, for example, PCDTPT, is casted on the dielectric layer 304, for example, by spin coating for the first transistor 310 and by slot-die coating for the second transistor 320. To facilitate the alignment of polymer film in the second transistor 320, the direction of the slot-die movement may be made parallel to the nanogrooves 309. In this manner, the polymer is brought into alignment by confining the solution in the pre-defined nanogrooves 309 on the substrate 302, and exerting external force induced by unidirectional solution flow. The semiconductor polymer layer of the first transistor 310 is referred to as the first semiconductor polymer layer 312 in which polymer chains are randomly aligned. The semiconductor polymer layer of the second transistor 320 is referred to as the second semiconductor polymer layer 322 in which polymer chains are aligned substantially parallel to the nanogrooves 309.

The electrodes 314, 316, 324, 326 of the first transistor 310 and the second transistor 320 are formed on the semiconductor polymer layers 312, 322. For example, source and drain electrodes with a channel length of 100 μm and a channel width of 500 μm are formed by thermal evaporation of gold (Au) through a shadow mask. The channel length and the channel width may be the same for the first transistor 310 and the second transistor 320. Accordingly, the first transistor 310 and the second transistor 320 have substantially the same channel width-to-length (W/L) ratio. Alternatively, the channel length and the channel width may be different for the first transistor 310 and the second transistor 320, as long as the channel W/L ratio is the same for the first transistor 310 and the second transistor 320. During the evaporation process, the channel length is also oriented parallel to the nanogrooves 309, in order to achieve anisotropic charge transport along the channel.

In an illustrative example, the random packing of the polymer in the first transistor 310 may result in the field effect mobility of about 1.46 cm²/V-s. In contrast, synergic effect of nanoconfinement and unidirectional solution flow suppresses the multiple degrees of conformational freedom of polymer chains in the solution phase for the second transistor 320, resulting in the long-ranged oriented polymer film 322 and high field effect mobility of about 5 cm²/V-s in the second transistor 320, and at the same time without physical change in the W/L ratio in the circuit design, as shown in FIGS. 3-6 above. Accordingly, the second transistor 320 formed using the method of various embodiments achieves higher transistor performance than the first transistor 310, while maintaining the same W/L ratio.

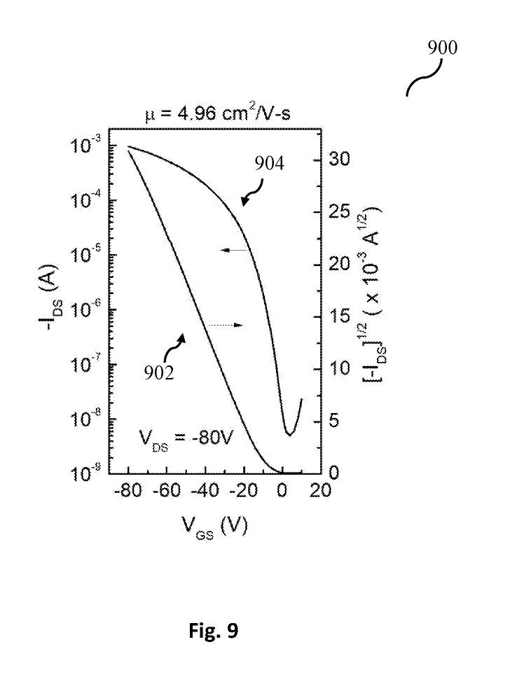

FIG. 8 shows transfer characteristics 800 of the first transistor 310 of FIG. 4 according to various embodiments, and FIG. 9 shows transfer characteristics 900 of the second transistor 320 of FIG. 5 according to various embodiments. The two transistors 310, 320 have substantially the same channel length and channel width.

In FIG. 8, the transfer charateristics 802, 804 represent the negative drain current (−I_{DS}) and the square root of the the negative drain current ([−I_{DS}]^{1/2}) of the first transistor 310 measured under a drain-source voltage (V_{DS}) of −80V and plotted as a function of the gate-source voltage (V_{GS}), respectively. In FIG. 9, the transfer charateristics 902, 904 represent the negative drain current (−I_{DS}) and the square root of the the negative drain current ([−I_{DS}]^{1/2}) of the second transistor 320 measured under a drain-source voltage (V_{DS}) of −80V and plotted as a function of the gate-source voltage (V_{GS}), respectively. As shown in FIG. 8, the first transistor 310 results in the field effect mobility of 1.49 cm²/V-s. FIG. 9 shows that the second transistor 320 results in higher field effect mobility of 4.96 cm²/V-s.

The transfer characteristics of the first transistor 310 and the second transistor 320 are close to “ideal” behaviours: (1) the slope of the square root of the −I_{DS} vs. V_{GS} in the saturated transfer characteristics is almost linear throughout the wide range of applied gate voltages, as shown in FIG. 8 and FIG. 9; and (2) low hysteresis is observed with multicycles of forward and reverse sweeping of the gate voltage (not shown here). These “near ideal” transfer characteristics suggest the low contact resistance and the low density of shallow traps at the polymer-dielectric interface even with nanogrooves. Field effect mobility was obtained in the saturation region of transistor operation using the equation, I_{DS} =(W/2L)C_{g}μ(V_{GS}−Vₜₕ)², where W/L is the channel width/length, C_{g} is the gate capacitance per unit area, Vₜₕ is the threshold voltage and μ is the field effect mobility. The mobility was extracted from the saturation region at low gate voltages (−20 V to −30 V).

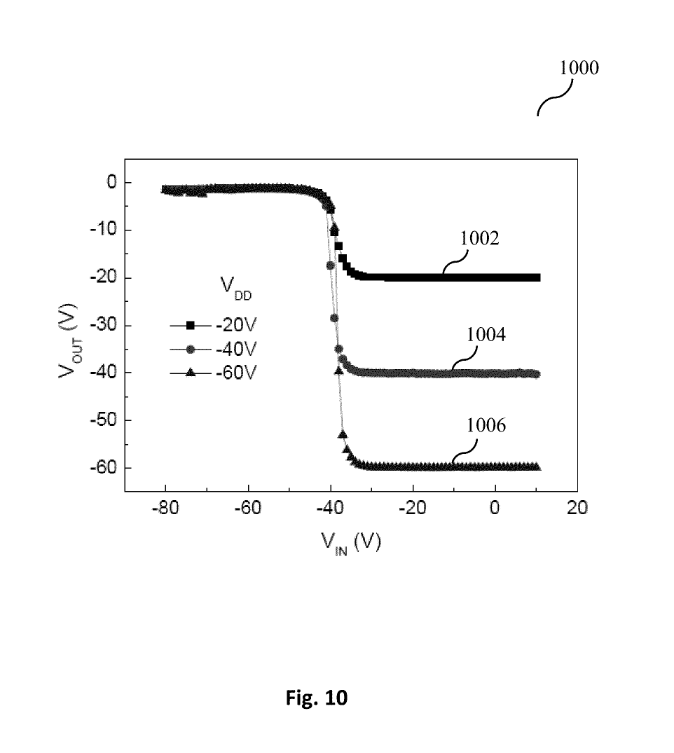

FIG. 10 shows transfer characteristics 1000 of the organic inverter of FIG. 3 according to various embodiments.

With the first transistor 310 and the second transistor 320 which have performance of 3-4 time difference as described above, the inverter logic gate 300 with fast switching speed and low noise margin is formed. In addition, the actual function of the circuit 300 is not revealed, since the first transistor 310 and the second transistor 320 have substantially the same channel width-to-length (W/L) ratio.

According to the voltage transfer characteristics of the organic inverter (in this example, a PMOS inverter) in FIG. 10, the inverter logic gate 300 with fast switching speed and low noise margin is built. The transfer characteristics 1002, 1004, 1006 correspond to the V_{OUT}-V_{IN} curves (i.e. output voltage vs. input voltage) of the inverter logic gate 300 at supply voltages V_{DD} of −20V, −40V and −60V, respectively. For example, as shown in the V_{OUT}-V_{IN} curve 1006, V_{OUT} of the inverter 300 exhibits a sharp inversion at V_{IN} of ˜ −40V at V_{DD} of −60V, which corresponds to a maximum voltage gain (−dV_{OUT}/dV_{IN}) of about 30.2 when W/L=1 is used for both transistors 310, 320.

According to various embodiments above, an inverter circuit design using organic transistors is provided, wherein the geometric ratio of two transistors (e.g., the ratio between the W/L ratio of the first transistor 310 and the W/L ratio of the second transistor 320) is about 1 with a tolerance of 50%. Accordingly, various embodiments provide a ratioed logic design of the inverter based on performance tuning of the transistors, but not based on geometrical changes of the transistors. In addition, the inverter of various embodiments does not require two different supply voltages at control terminals (e.g. gate electrodes) of the transistors, but only uses one supply voltage, for example, as shown in FIG. 7. The inverter also does not require adjustment of threshold voltages of the transistors.

According to various embodiments, a circuit design using organic transistors which does not reveal the function of the circuit is provided, by manipulating the transistor performance through semiconducting polymer alignment. By using the in-situ method of changing polymer transistor performance to make one transistor performance better (e.g. 3-4 times) than another transistor with the same design (e.g., substantially the same W/L ratio with 50% tolerance), desired performance of the inverter circuit can be achieved.

The layout of the inverter circuit according to various embodiments has hidden circuit design stratagem, e.g. as shown in FIG. 6, which makes it difficult for tapping the circuit and thus enables circuit design security for printed circuits. Accordingly, the inverter circuit of various embodiments above can be applied in printed electronics for security package, anti-tapping, authentication, etc.

The inverter of various embodiments above and formed using the method of various embodiments achieves many advantages over the existing ratioed design. Compared with the inverter design of FIG. 1(a), the inverter of various embodiments is achieved in a compact design and improved integration density. The inverter of various embodiments reduces the area of the circuit, and reduces the high impedance. Compared with the inverter design of FIG. 1(b), the inverter of various embodiments does not need to reduce the channel length to meet the performance requirement on the load and driving transistors, and thus has no restriction on the printing resolution. Accordingly, the layout of the inverter circuit according to various embodiments can use optimized printing resolution and circuit performance to design the circuits for maximum yield.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of forming an organic inverter comprising a first transistor and a second transistor, the method comprising:
providing a substrate with a dielectric layer formed on top of the substrate;
depositing a first semiconductor polymer layer on a first region of the dielectric layer;
forming a first electrode and a second electrode on the first semiconductor polymer layer, thereby forming the first transistor located at the first region of the dielectric layer;
forming a plurality of grooves on a surface of a second region of the dielectric layer;
depositing a second semiconductor polymer layer on the second region of the dielectric layer;
forming a first electrode and a second electrode on the second semiconductor polymer layer, thereby forming the second transistor located at the second region of the dielectric layer.

2. The method of claim 1, wherein the substrate comprises one of a silicon substrate, a glass substrate, a polyethylene terephthalate substrate, a polyethylene naphthalate substrate, or a polyimide substrate.

3. The method of claim 1, comprising:
forming the first transistor and the second transistor with substantially the same channel width-to-length ratio.

4. The method of claim 1, comprising:
depositing the first semiconductor polymer layer on the first region of the dielectric layer by one of spin coating, drop casting, dip coating, inkjet, grovure printing, flexographic printing, Langmuir-Blodgett depositions, or doctor blading.

5. The method of claim 1, comprising:
forming the plurality of grooves by scratching the surface of the second region of the dielectric layer using diamond lapping film.

6. The method of claim 1, wherein the plurality of grooves comprises nanoscale grooves with a depth in a range of 1 nm to 5 nm.

7. The method of claim 1, wherein
the plurality of grooves is at least substantially parallel to each other.

8. The method of claim 1, comprising:
directionally depositing the second semiconductor polymer layer on the second region of the dielectric layer by one of slot-die coating, dip coating, grovure printing, flexographic printing, Langmuir-Blodgett depositions, or doctor blading; or depositing the second semiconductor polymer layer on the second region of the dielectric layer by one of drop casting or inkjet printing.

9. The method of claim 8, further comprising:
directionally depositing the second semiconductor polymer layer along a direction at least substantially parallel to longitudinal axes of the plurality of grooves.

10. The method of claim 1, comprising:
forming the first electrode and the second electrode of the second transistor such that a channel length between the first electrode and the second electrode is at least substantially parallel to longitudinal axes of the plurality of grooves.

11. The method of claim 1, wherein at least one of the first semiconductor polymer layer or the second semiconductor polymer layer comprises one of PCDTPT, P3HT, PPV, or PBTTT.

12. An organic inverter, comprising:
a substrate with a dielectric layer formed on top of the substrate;
a first transistor located at a first region of the dielectric layer, the first transistor comprising a first semiconductor polymer layer on the first region of the dielectric layer, and comprising a first electrode and a second electrode on the first semiconductor polymer layer; and
a second transistor located at a second region of the dielectric layer, the second transistor comprising a second semiconductor polymer layer on the second region of the dielectric layer, and comprising a first electrode and a second electrode on the second semiconductor polymer layer;
wherein the dielectric layer comprises a plurality of grooves on a surface of the second region of the dielectric layer contacting the second semiconductor polymer layer.

13. The organic inverter of claim 12, wherein the substrate comprises one of a silicon substrate, a glass substrate, a polyethylene terephthalate substrate, a polyethylene naphthalate substrate, or a polyimide substrate.

14. The organic inverter of claim 12, wherein
the first transistor further comprises a third electrode in the substrate, the third electrode of the first transistor being a gate electrode and being located under the first region of the dielectric layer; and
the second transistor further comprises a third electrode in the substrate, the third electrode of the second transistor being a gate electrode and being located under the second region of the dielectric layer.

15. The organic inverter of claim 12, wherein
the first transistor and the second transistor have substantially the same channel width-to-length ratio.

16. The organic inverter of claim 12, wherein
polymer chains of the first semiconductor polymer layer are randomly aligned.

17. The organic inverter of claim 12, wherein
polymer chains of the second semiconductor polymer layer are aligned substantially along a direction from the first electrode to the second electrode of the second transistor.

18. The organic inverter of claim 12, wherein the plurality of grooves comprises a plurality of nanoscale grooves with a depth in a range of 1 nm to 5 nm.

19. The organic inverter of claim 12, wherein
the plurality of grooves is at least substantially parallel to each other.

20. The organic inverter of claim 12, wherein
a channel length between the first electrode and the second electrode of the second transistor is at least substantially parallel to longitudinal axes of the plurality of grooves.
